(19) United States
(12) Patent Application Publication
(10) Pub. No.: US 2011/0147687 A1
(43) Pub. Date: Jun. 23, 2011

(54) EXTENDABLE BALUSTER ASSEMBLY

(76) Inventor: JEAN SGARIGLIA, Terrebonne (CA)

(21) Appl. No.: 12/694,513

(22) Filed: Jan. 27, 2010

(30) Foreign Application Priority Data
Dec. 23, 2009 (CA) 2,687,925

(51) Int. Cl. E04F 11/18; H05K 13/00

(52) U.S. Cl. 256/65.02; 29/592.1

(57) ABSTRACT

There is provided an extendable baluster assembly for use with a handrail, the extendable baluster assembly comprising a baluster comprising an inner member and an outer member circumscribing a portion of the inner member in a telescopic relation, the outer member being fixable to the inner member; and a railing connector having a tubular body defining a cavity for receiving a top end of the baluster. There is also provided an extendable baluster assembly for use with a handrail, the extendable baluster assembly comprising a telescopic baluster; a ground connector adapted to be attached to a ground surface; a railing connector adapted to be attached to a handrail; and rotational joints between the baluster and the railing connector, and between the baluster and the ground connector, whereby the baluster is rotatable.

### CROSS-REFERENCE TO RELATED APPLICATIONS

This application claims priority of Canadian patent application 2,687,925 filed Dec. 23, 2009.

### FIELD OF THE APPLICATION

The technical field relates generally to railings, and more particularly to extendable balusters and installation of railings with such balusters.

### BACKGROUND OF THE ART

Railings may be used in a number of different locations, such as on a porch, on a stairway, or in any area where fencing or additional support for one's hand may be advantageous and/or convenient. In railings, balusters are used with handrails in order to support the handrail and/or to provide additional aesthetic appeal. Railings may be constructed at an angle and may be provided at different heights and so, it may often be necessary to adapt the corresponding balusters to accommodate for these different heights.

In order to provide for handrails having different elevations from the ground, certain balusters of the prior art have been known to use telescopic members for additional extension. These balusters with telescopic members often comprise handrail connectors. Such connectors may be bulky and thus lack aesthetic appeal. Moreover, some handrail connectors include various joints (e.g., pivots, sliding joints) to interface the baluster to given angles of handrails. Railings including balusters may often be installed by handymen or normal workers, without specialized carpentry skills. As such, it may be desirable to provide a baluster requiring little or no adjustment in order to simplify railing installation procedure.

### SUMMARY OF THE APPLICATION

In accordance with one aspect, there is provided an extendable baluster assembly for use with a handrail, the extendable baluster assembly comprising: a baluster comprising an inner member and an outer member circumscribing a portion of the inner member in a telescopic relation, the outer member being fixable to the inner member; and a railing connector having a tubular body defining a cavity for receiving a top end of the baluster, with an inner annular wall in the tubular body, the tubular body having an upper rim and a bottom rim, the inner annular wall being positioned radially with respect to the tubular body such that the inner annular wall is perpendicular to a central axis of the tubular body, the inner annular wall having a fastener bore located therethrough, a fastener being inserted through the fastener bore and into the handrail, such that the railing connector is fixed to the handrail.

In accordance with a further aspect, there is provided an extendable baluster assembly for use with a handrail, the extendable baluster assembly comprising: a baluster being telescopic with ends each having a generally circular cross-section; a ground connector adapted to be attached to a ground surface, and defining a cavity of generally circular cross-section to receive a bottom end of the baluster; a railing connector adapted to be attached to a handrail, and defining a cavity of generally circular cross-section to receive a top end of the baluster; and rotational joints between the baluster and the railing connector, and between the baluster and the ground connector, the rotational joints having a coincident rotational axis normal to the ground when the baluster is vertical, whereby the baluster is rotatable about the rotational axis with respect to the ground and railing connectors.

In accordance with another further aspect, there is provided A method for installing an extendable baluster assembly comprising: attaching a ground connector to a ground surface, attaching a railing connector to a handrail, inserting a telescopic baluster into a cavity of the ground connector, extending the telescopic baluster to the railing connector until a top end of the telescopic baluster enters a cavity of the railing connector, and fixing the length of the telescopic baluster using a fastener.

### BRIEF DESCRIPTION OF THE DRAWINGS

FIG. 1 is a front perspective view, partly fragmented, of an extendable baluster assembly according to one embodiment of the present disclosure;

FIG. 2 is a top perspective view of a railing connector of the extendable baluster assembly of FIG. 1;

FIG. 3 is a sectional view of the railing connector of FIG. 2, attached to a handrail; and

FIG. 4 is a sectional view of a ground connector of the extendable baluster assembly of FIG. 1, attached to the ground.

### DESCRIPTION OF THE PREFERRED EMBODIMENTS

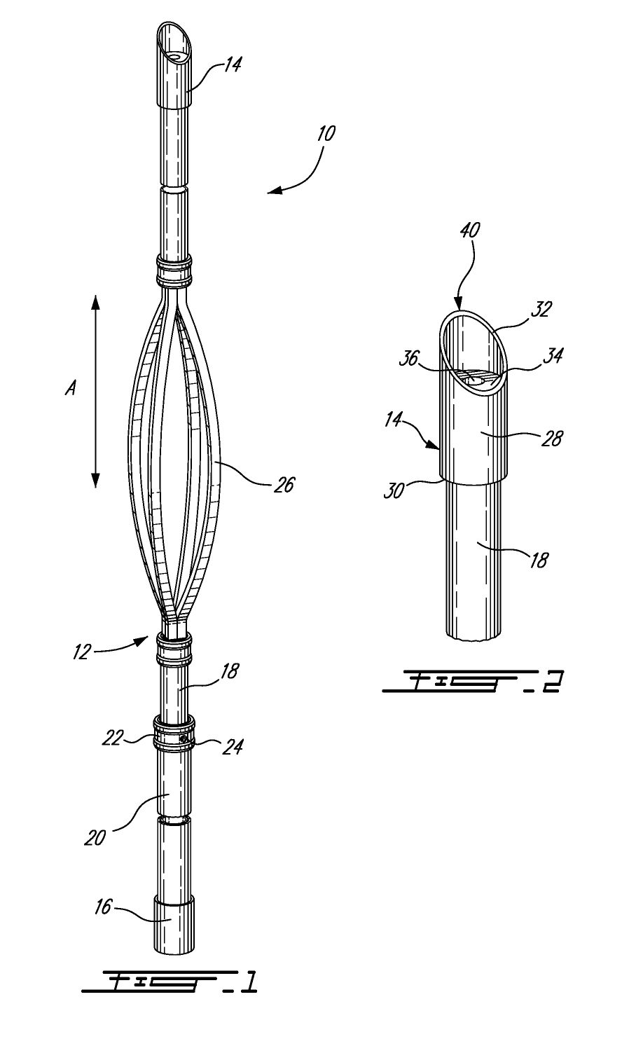

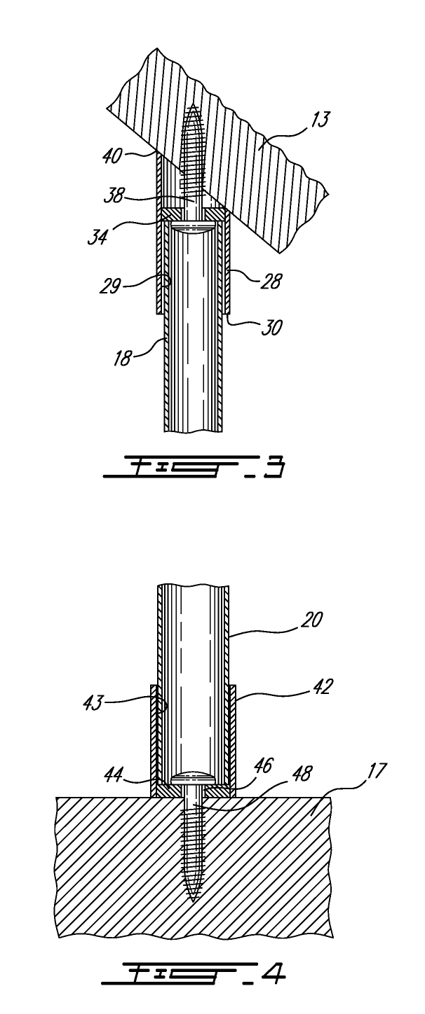

The extendable baluster assembly 10 may generally be used as a connection element between a handrail and a ground surface, such as the steps in a staircase. FIG. 1 shows one embodiment of an extendable baluster assembly 10. The extendable baluster assembly 10 comprises a baluster 12 which serves to support a handrail 13 (FIG. 3), a railing connector 14 for receiving the baluster 12 and which is attached to the handrail 13, and a ground connector 16 for receiving the baluster 12 and which is attached to a ground surface 17 (FIG. 4), such as a step of a staircase or a floor.

The baluster 12 is telescopic and comprises an inner tubular member 18 and an outer tubular member 20 which circumscribes a portion of the inner tubular member 18. The inner and outer tubular members 18 and 20 may translate relative to one another in the direction shown by A, and so the baluster 12 may extend in order to comprise different lengths. Moreover, due to a generally circular cross-section of the tubular members 18 and 20, the tubular members may rotate with respect to one another until they are locked together. The baluster 12 may therefore extend and be sized so as to support handrails at different elevations from the ground.

The inner and outer tubular members 18, 20 may have a generally circular cross-section, which is of a diameter smaller than that of the railing connector 14 and of the ground connector 16, such that an upper end of the inner tubular member 18 may be received inside at least a portion of the railing connector 14 and a bottom end of the outer tubular member 20 may be received inside at least a portion of the ground connector 16. Alternatively, in another embodiment, the inner tubular member 18 may be received inside the ground connector 16 and the outer tubular member 20 may be received inside the railing connector 14. Other cross-sectional shapes are considered for the tubular members 18, 20. Also, the inner member 18 may be solid and thus not tubular.

The outer tubular member 20 has a collar portion 22 at an upper end thereof. The collar portion 22 has a fastener hole 24 therethrough. A fastener (not shown) may be inserted through the fastener hole 24 and against or into the inner tubular member 18, so as to lock the inner tubular member 18 to the outer tubular member 20 at a desired height, and so limit rotational and translational movement of the tubular members 18, 20 relative to one another. The fastener may comprise various types of fasteners, such as a screw, setscrew, bolt, nail, etc.

In another embodiment, the collar portion 22 may be located at another position along the outer tubular member 20 and therefore not necessarily be at an end thereof. In another embodiment, the collar portion may comprise a plurality of fastener holes 24, such that a plurality of fasteners may be used to fix the outer tubular member 20 to the inner tubular member 18.

In one embodiment, the inner tubular member 18 may comprise an aesthetic portion 26. The aesthetic portion 26 may include a number of different artistic elements, so as to improve or customize the appearance of the extendable baluster assembly 10. The embodiment of FIG. 1 shows only one example of a possible aesthetic portion 26. However, in other embodiments, the aesthetic portion 26 may comprise different artistic elements.

As seen in FIGS. 2 and 3, the railing connector 14 comprises a tubular body 28 defining a cavity 29 therein for receiving an end of the inner tubular member 18. The tubular body 28 has a bottom rim 30 at a lower extremity thereof and an upper rim 32 at an opposite top extremity thereof. When used with a substantially vertical baluster 12, the upper rim 32 is inclined at an angle ranging between 38 and 46 degrees from the ground. In an embodiment, the angle of the upper rim 32 is 42 degrees from the ground, having an upper rim 32 angled at 42 degrees allows the extendable baluster assembly 10 to be attached to most handrails with little or minimal gap between the upper rim 32 and a bottom surface of the handrail 13. As the railing connector 14 is positioned on a bottom surface of the handrail 13, the upper rim 32 may generally be coplanar with the bottom surface of the handrail 13, and as such, may be attached without requiring additional positioning adjustments.

The railing connector 14 also comprises an inner annular wall 34 which is positioned radially with respect to the tubular body 28, such that the inner annular wall 34 is perpendicular to a longitudinal axis of the tubular body 28. As seen in FIG. 2, the inner annular wall 34 may be longitudinally offset from the upper rim 32. The inner annular wall 34 has a fastener bore 36 located therethrough. A fastener 38 may be inserted through the fastener bore 36 and into the handrail 13, in order to attach the railing connector 14 to the handrail 13, with the head of the fastener 38 cooperating with the annular wall 34 to hold the railing connector 14 captive. As seen in FIG. 3, the fastener 38 may be inserted through the fastener bore 36 and into the handrail 13, from a bottom vantage point. This allows for a rapid installation, in comparison to balusters where the baluster must be attached to the handrail through the handrail itself. The installation may be simplified if the fastener 38 is a self-tapping fastener.

In addition, the upper rim 32 may include a relatively pointy tip 40 at an upper extremity thereof. More specifically, by the combination of the inclination of the upper rim 32 and the circular section, the upper rim 32 defines the pointy tip 40. In one embodiment, the pointy tip 40 may be used to indent and penetrate into the handrail 13 if the material is relatively soft (e.g., wood, plastic), in order to provide additional stability to the railing connector 14 and the baluster 12, as desired. Accordingly, the pointy tip 40 may reduce any gap between the upper rim 32 and the handrail 13 if any.

The ground connector 16 comprises a tubular body 42 and a cavity 43 therein for receiving the outer tubular member 20. The tubular body 42 has an inner annular wall 44 located radially with respect to the tubular body 42. The inner annular wall 44 includes a fastener bore 46 located therethrough. A fastener 48 may be inserted through the fastener bore 46 and into the ground 17, so as to attach the ground connector 16 to the ground 17, with the head of the fastener 48 cooperating with the annular wall 44 to hold the ground connector 16 captive.

As mentioned, the inner and outer tubular members 18, 20 may have a generally circular cross-section, and therefore the baluster 12 may also have a generally circular cross-section. Accordingly, rotational joints are formed between the baluster 12, and the connectors 14 and 16, with a rotational axis being normal to the ground when the baluster 12 is installed vertically. In addition, although the inner and outer tubular members 18, 20 may be received inside the railing connector 14 and the ground connector 16, the inner and outer tubular members 18, 20 may not be attached to said connectors 14, 16. Therefore, the baluster 12 is free to rotate inside the connectors 14, 16, relative to said connectors 14, 16, the handrail 13 and the ground 17. The baluster 12 is rotatable as desired, for example to hide any fasteners visible from the outside, to prevent injuries to young children who may get caught inside the baluster's aesthetic portion 26, or simply for aesthetic purposes. For example, the aesthetic portion 26 may look differently depending on the angle or the position at which a person is looking at it, and so the baluster 12 may be rotated in order to present a particular view to a certain position, as desired.

Now that the components of the extendable baluster assembly 10 are described, an installation thereof is set forth. The extendable baluster assembly 10 may be installed by either first attaching the railing connector 14 or the ground connector 16 to the handrail 13 or ground surface 17, respectively. The railing connector 14 is attached to the handrail 13 by positioning the railing connector 14 on the handrail 13 and by inserting the fastener 38 through the fastener bore 36 and into the handrail 13. A direction of insertion of the fastener 38 is thus essentially normal to the ground.

If necessary, the railing connector 14 may be pressed against a bottom surface of the handrail 13 to make an indent and thus reduce any gap between the upper rim 32 and the handrail 13.

The ground connector 16 is attached to the ground surface 17 by positioning the ground connector 16 on the ground 17, and by inserting the fastener 48 through the fastener bore 46 and into the ground 17. In a preferred embodiment, the railing connector 14 and the ground connector 16 may be positioned with respect to each other, such that the baluster 12 located therebetween is substantially vertical, i.e. straight.

Having attached the railing connector 14 and the ground connector 16, the baluster 12 may be received inside a portion of one of the connectors 14, 16, and the inner and outer tubular members 18, 20, may be translated relative to one another, such that the baluster 12 is received inside both of the connectors 14, 16, and is extended therebetween to the desired height. The fastener (not shown) may then be inserted through the fastener hole 24 of the collar portion 22 of the outer tubular member 20, such that relative movement between the inner and outer tubular members 18, 20 is minimized, and the length of the baluster 12 is fixed.

An orientation of the baluster 12 may be adjusted by the rotation of the baluster 12 with respect to the connectors 14, 16. The axis of rotation of the baluster 12 is normal to the ground when the baluster 12 is vertical.

This installation method should not be limited to this specific order of steps, i.e. the steps are interchangeable, for example, the ground connector 16 may be attached to the ground 17 and the baluster 12 may be inserted into the ground connector 16, prior to attaching the railing connector 14 to the handrail 13.

The extendable baluster assembly 10 is generally made of metal, although in other embodiments, a number of different types of metals, plastics or woods may also be used. The extendable baluster assembly 10 may generally be used with handrails on stairways, or with handrails on other types of inclined surfaces.

The above description is meant to be exemplary only, and one skilled in the art will recognize that changes may be made to the embodiments described without departing from the scope of the invention disclosed. For example, the extendable baluster assembly may also be used with a handrail on a flat surface, by simply having the pointy end of the upper rim of the railing connector perforate and penetrate into the handrail. Still other modifications which fall within the scope of the present invention will be apparent to those skilled in the art, in light of a review of this disclosure, and such modifications are intended to fall within the appended claims.

1. An extendable baluster assembly for use with a handrail, the extendable baluster assembly comprising:
a baluster comprising an inner member and an outer member circumscribing a portion of the inner member in a telescopic relation, the outer member being fixable to the inner member; and
a railing connector having a tubular body defining a cavity for receiving a top end of the baluster, with an inner annular wall in the tubular body, the tubular body having an upper rim and a bottom rim, the inner annular wall being positioned radially with respect to the tubular body such that the inner annular wall is perpendicular to a central axis of the tubular body, the inner annular wall having a fastener bore located therethrough, a fastener being inserted through the fastener bore and into the handrail, such that the railing connector is fixed to the handrail.

2. The extendable baluster assembly as defined in claim 1, wherein the inner annular wall is longitudinally offset from the upper rim.

3. The extendable baluster assembly as defined in claim 1, wherein a plane of the upper rim is angled at 42 degrees with respect to a plane of the bottom rim.

4. The extendable baluster assembly as defined in claim 1, wherein the upper rim has a pointy end, such that the pointy end is used to indent the handrail.

5. The extendable baluster assembly as defined in claim 1, wherein the extendable baluster assembly further comprises a ground connector having a cavity therein, the baluster extending into at least a portion of the cavity of the ground connector, the ground connector having a tubular body and an inner annular wall, the inner annular wall having a fastener bore located therethrough, a fastener being positioned through the fastener bore and into a ground surface, such that the ground connector is fixed to the ground.

6. The extendable baluster assembly as defined in claim 5, wherein the opposed ends of the baluster and the cavities of the railing connector and of the ground connector each have a generally circular cross-section, to define rotational joints between the baluster and the railing connector, and between the baluster and the ground connector, the rotational joints having a coincident rotational axis normal to the ground when the baluster is vertical.

7. The extendable baluster assembly as defined in claim 1, wherein the outer member has a collar portion having a fastener hole therethrough, such that a fastener is inserted through the fastener hole and against/into the inner tubular member, in order to fix the outer member to the inner member.

8. The extendable baluster assembly as defined in claim 5, wherein the inner member is received inside the railing connector and the outer member is received inside the ground connector.

9. An extendable baluster assembly for use with a handrail, the extendable baluster assembly comprising:
a baluster being telescopic with ends each having a generally circular cross-section;
a ground connector adapted to be attached to a ground surface, and defining a cavity of generally circular cross-section to receive a bottom end of the baluster;
a railing connector adapted to be attached to a handrail, and defining a cavity of generally circular cross-section to receive a top end of the baluster; and
rotational joints between the baluster and the railing connector, and between the baluster and the ground connector, the rotational joints having a coincident rotational axis normal to the ground when the baluster is vertical, whereby the baluster is rotatable about the rotational axis with respect to the ground and railing connectors.

10. The extendable baluster assembly as defined in claim 9, wherein the baluster comprises an inner member and an outer member circumscribing a portion of the inner member in a telescopic relation, the outer member being fixable to the inner member.

11. The extendable baluster assembly as defined in claim 9, wherein the inner annular wall is longitudinally offset from the upper rim.

12. The extendable baluster assembly as defined in claim 9, wherein a plane of the upper rim is angled at 42 degrees with respect to a plane of the bottom rim.

13. The extendable baluster assembly as defined in claim 1, wherein the upper rim has a pointy end, such that the pointy end is used to indent the handrail.

14. A method for installing an extendable baluster assembly comprising:
attaching a ground connector to a ground surface,
attaching a railing connector to a handrail,
inserting a telescopic baluster into a cavity of the ground connector,
extending the telescopic baluster to the railing connector until a top end of the telescopic baluster enters a cavity of the railing connector, and
fixing the length of the telescopic baluster using a fastener.

15. The method as defined in claim 14, wherein fixing the length of the telescopic baluster comprises inserting a fastener through members of the telescopic baluster in telescopic relation.

16. The method as defined in claim 14, wherein attaching a ground connector comprises inserting a fastener through a fastener bore of the ground connector and into the ground surface.

17. The method as defined in claim 14, wherein attaching a railing connector comprises inserting a fastener through a fastener bore of the railing connector and into the handrail, in a direction generally normal to the ground.

18. The method as defined in claim 14, further comprising rotating the telescopic baluster along a rotational axis normal to the ground to adjust an orientation of the telescopic baluster.

19. The method as defined in claim 14, wherein attaching a railing connector further comprises making an indentation in the handrail using a pointy end of the railing connector.
